(19) United States
(12) Patent Application Publication
(10) Pub. No.: US 2024/0426020 A1
(43) Pub. Date: Dec. 26, 2024

(54) HALOGEN PLASMA ETCH-RESISTANT SILICON CRYSTALS

(71) Applicant: SILFEX, INC., Eaton, OH (US)

(72) Inventors: Jihong CHEN, Cincinnati, OH (US); Rong WANG, Springboro, OH (US); Jun YAN, Reading, MA (US); Vijay NITHIANATHAN, Springboro, OH (US)

(21) Appl. No.: 18/707,944

(22) PCT Filed: Nov. 2, 2022
(86) PCT No.: PCT/US2022/048645

§ 371 Date: May 7, 2024

Related U.S. Application Data
(60) Provisional application No. 63/276,984, filed on Nov. 8, 2021.

(51) Int. Cl. C30B 15/04; C30B 29/06; C30B 29/60

(52) U.S. Cl. CPC C30B 15/04; C30B 29/06; C30B 29/60

(57) ABSTRACT

Various compositions of a material resistant to etching when exposed to halogen plasma are disclosed. The compositions include silicon and a dopant, with silicon having a purity of at least 6N (i.e., including impurities other than silicon and the dopant of less than 1 ppm-mass), and the dopant having a purity of at least 4N (i.e., including impurities of less than 100 ppm-mass). The dopant can be selected from a group consisting of boron, gallium, phosphorous, arsenic, and antimony, Specific concentrations for each dopant are disclosed. At these concentrations, the material exhibits a relatively low etch rate when exposed to halogen plasma. Additionally, at these concentrations, no precipitates of the dopant are formed during crystal growth. Components of substrate processing chambers manufactured from the material exhibit relatively high resistivity to etching when exposed to halogen plasma in the substrate processing chambers.

### CROSS-REFERENCE TO RELATED APPLICATIONS

This application claims the benefit of U.S. Provisional Application No. 63/276,984, filed on Nov. 8, 2021. The entire disclosure of the above application is incorporated herein by reference.

### FIELD

The present disclosure relates generally to semiconductor materials and more particularly to halogen plasma etch resistant silicon crystals.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to treat substrates such as semiconductor wafers. Examples of processes that may be performed on a substrate include, but are not limited to, chemical vapor deposition (CVD), atomic layer deposition (ALD), conductor etch, dielectric etch, rapid thermal processing (RTP), ion implant, physical vapor deposition (PVD), and/or other etch, deposition, or cleaning processes. A substrate may be arranged on a substrate support, such as a pedestal, an electrostatic chuck (ESC), etc. in a processing chamber of the substrate processing system. During processing, gas mixtures may be introduced into the processing chamber and plasma may be used to initiate and sustain chemical reactions.

The processing chamber includes various components including, but not limited to, the substrate support, a gas distribution device (e.g., a showerhead, which may also correspond to an upper electrode), a plasma confinement ring or shroud, etc. The substrate support may include a ceramic layer arranged to support a wafer. For example, the wafer may be clamped to the ceramic layer during processing. The substrate support may include an edge ring arranged around an outer portion (e.g., outside of and/or adjacent to a perimeter) of the substrate support. The edge ring may be provided to modify a plasma sheath above the substrate, optimize substrate edge processing performance, protect the substrate support from erosion caused by the plasma, etc. The plasma confinement shroud may be arranged around each of the substrate support and the showerhead to confine the plasma within the volume above the substrate.

### SUMMARY

A component of a substrate processing chamber comprises silicon, a dopant, and one or more impurities other than the silicon and the dopant of less than 1 ppm-mass. The dopant is selected from a group consisting of boron or gallium at a concentration of 0.05 wt % to 0.5 wt %, phosphorous at a concentration of 0.5 wt % to 5.0 wt %, arsenic at a concentration of 1.5 wt % to 15.0 wt %, and antimony at a concentration of 0.1 wt % to 1.0 wt %.

In another feature, the concentration of the dopant is in the ranges of 0.1 wt % to 0.3 wt % if the dopant is boron or gallium, 1.0 wt % to 3.0 wt % if the dopant is phosphorous, 3 wt % to 10 wt % if the dopant is arsenic, and 0.2 wt % to 0.7 wt % if the dopant is antimony.

In another feature, the component does not include precipitates containing the dopant.

In another feature, the component includes at least one of a C-shaped plasma confinement shroud, an L-shaped plasma confinement ring, an edge ring, an electrode, a sidewall of the substrate processing chamber, a window in the substrate processing chamber, and a dome of the substrate processing chamber.

In still other features, a method of forming a material comprises forming a mixture of silicon and a dopant, melting the mixture, and solidifying the melted mixture from a bottom of the melted mixture to form the material. The silicon comprises one or more impurities other than the silicon and the dopant of less than 1 ppm-mass. The dopant comprises one or more impurities of less than 100 ppm-mass. The dopant is selected from a group consisting of boron or gallium at a concentration of 0.05 wt % to 0.5 wt %, phosphorous at a concentration of 0.5 wt % to 5.0 wt %, arsenic at a concentration of 1.5 wt % to 15.0 wt %, and antimony at a concentration of 0.1 wt % to 1.0 wt %. The dopant comprises one or more impurities of less than 100 ppm-mass.

In another feature, the concentration of the dopant is in the ranges of 0.1 wt % to 0.3 wt % if the dopant is boron or gallium, 1.0 wt % to 3.0 wt % if the dopant is phosphorous, 3 wt % to 10 wt % if the dopant is arsenic, and 0.2 wt % to 0.7 wt % if the dopant is antimony.

In another feature, the material is resistant to etching by halogen plasma.

In another feature, the material does not include precipitates containing the dopant.

In another feature, the method further comprises machining the material to form a component of a substrate processing chamber. The component includes at least one of a C-shaped plasma confinement shroud, an L-shaped plasma confinement ring, an edge ring, an electrode, a sidewall of the substrate processing chamber, a window in the substrate processing chamber, and a dome of the substrate processing chamber.

In another feature, the component is resistant to etching by halogen plasma when exposed to the halogen plasma in the substrate processing chamber.

In another feature, the component does not include precipitates containing the dopant.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a directional solidification system (DSS) for manufacturing a silicon ingot with a specific dopant concentration according to the present disclosure;

FIG. 2 shows an example of a system implementing a continuous Czochralski (CCZ) process for manufacturing a silicon ingot with a specific dopant concentration according to the present disclosure;

FIG. 3 shows a partial cross-section of an example of a plasma processing chamber in which etch-resistant components manufactured from silicon ingots produced using the systems of FIGS. 1 and 2 can be used;

FIGS. 4A and 4B show an example of a C-shaped plasma confinement ring or shroud used in the plasma processing chamber of FIG. 3, which can be manufactured from etch-resistant silicon ingots produced using the systems of FIGS. 1 and 2;

FIG. 5A shows an example of an L-shaped confinement ring for use in the plasma processing chamber of FIG. 3, which can be manufactured from etch-resistant silicon ingots produced using the systems of FIGS. 1 and 2;

FIG. 5B shows an example of a C-shaped shroud formed using the L-shaped confinement ring, which can be manufactured from etch-resistant silicon ingots produced using the systems of FIGS. 1 and 2;

FIGS. 6A and 6B show examples of embodiments utilizing the L-shaped confinement ring, which can be manufactured from etch-resistant silicon ingots produced using the systems of FIGS. 1 and 2;

FIGS. 7-9 show examples of substrate processing systems comprising processing chambers that can utilize etch-resistant components manufactured from silicon ingots produced using the systems of FIGS. 1 and 2;

FIG. 10 shows an example of an edge coupling ring for use in a processing chamber, which can be manufactured from etch-resistant silicon ingots produced using the systems of FIGS. 1 and 2;

FIG. 11 shows a method of forming a material comprising silicon and a dopant using the system of FIG. 1 or FIG. 2; and

FIG. 12 shows a method of forming a component by machining the material formed using the method of FIG. 11.

In the drawings, reference numbers may be reused to identify similar and/or identical elements.

### DETAILED DESCRIPTION

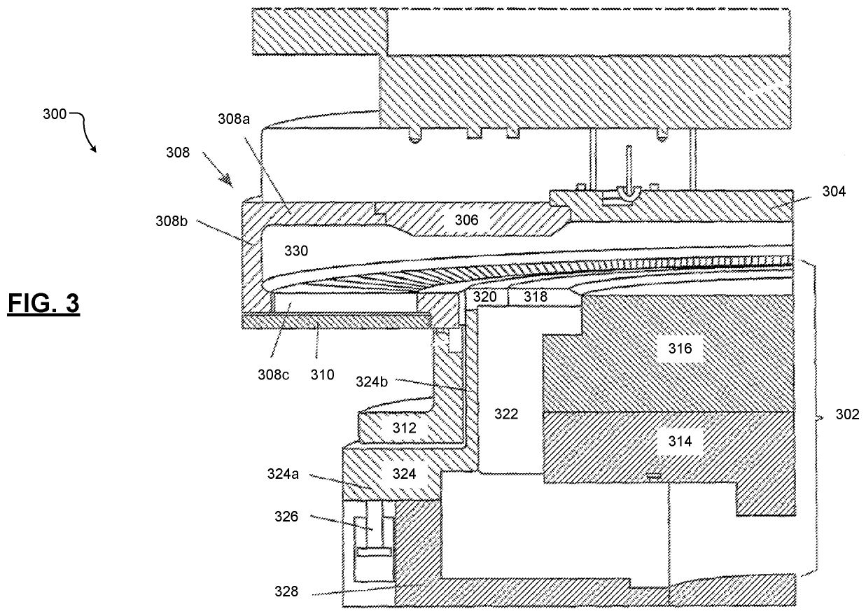

Many processes used to process substrates such as semiconductor wafers in processing chambers use halogen plasma to deposit and/or etch materials on the substrates. Additionally, some cleaning processes that are used to clean the processing chambers also use halogen plasma to clean the processing chambers. The halogen plasma used in these processes is very corrosive and etches surfaces of various components of the processing chambers. Non-limiting examples of the components include electrodes, C- and L-shaped plasma confinement rings, and edge rings. Examples of plasma chambers including these components are shown and described with reference to FIGS. 3-10. Continued exposure to halogen plasma over an extended period of time causes changes in these components of the processing chambers due to excessive etching of the surfaces of the components by the halogen plasma. The changes reduce process yield. Additionally, the useful life of these components is also significantly shortened. Consequently, these components need to be frequently refurbished and/or replaced, which results in increased down time and higher costs of consumables used in the processing chambers.

The present disclosure provides a material for making the components of the processing chambers that is resistant to etching by halogen plasma. Specifically, the material includes silicon crystals grown with a specific concentration of a dopant such as boron or other dopants as described below. Due to the specific concentration of the dopant used in growing the silicon crystals, the components made from the silicon crystals are resistant to etching from halogen plasma. By being resistant to etching from halogen plasma, the useful life of the components is extended. Consequently, the downtime and costs of consumables used in the processing chambers are reduced.

To be resistant to etching from halogen plasma, the components of the processing chambers can be manufactured using silicon crystals doped with a dopant such as boron or other dopants described below. However, if the concentration of the dopant is not controlled during the manufacture of the silicon crystals, dopant precipitates (e.g., boron precipitates denoted as SiBx, x>1) can form in the silicon crystals. Due to the presence of the dopant precipitates, the resulting silicon crystals do not exhibit the required resistance to etching by halogen plasma. In addition, the dopant precipitates pose particle contamination risks in the processing chambers. Therefore, silicon crystals with dopant precipitates are not suitable for manufacturing plasma facing components of the processing chambers.

To solve the above problems, as described below in detail, the present disclosure provides a material containing high purity silicon and a high purity dopant of specific concentration that has relatively low etch rates when exposed to halogen plasma. The specific concentration of the dopant prevents formation of dopant precipitates in silicon ingots. The specific concentration of the dopant also exhibits relatively low variation in dopant concentration from top to bottom of the silicon ingot. Accordingly, components made from the silicon ingots have uniform dopant concentration and resist etching due to halogen plasma in processing chambers.

For example, the present disclosure provides silicon crystals doped with boron concentration controlled within a specific range (0.05 wt % to 0.5 wt %, preferably 0.1 wt % to 0.3 wt %). Throughout the present disclosure, boron is used as an example of a dopant to illustrate the processes of forming silicon ingots according to the present disclosure. These processes can also be used to manufacture silicon ingots with other dopants described below.

By controlling the boron concentration within the specific range, silicon crystals without boron precipitates can be manufactured. Due to the absence of the boron precipitates, components of the processing chambers manufactured using these silicon crystals exhibit increased resistance to etching (i.e., reduced etch rates) by halogen plasma. Contamination risks posed by boron precipitates are also reduced. The silicon crystal with the specific boron concentration according to the present disclosure can be formed using directional solidification system (DSS), Czochralski (CZ) process (also called crystal pulling), or continuous Czochralski (CCZ) process, which are described below in detail.

At a given temperature, there is an upper limit for the amount of an impurity (e.g., a dopant such as boron) that can be dissolved in silicon. The upper limit is called a solid-solubility limit for the impurity. The ductile to brittle transition (DBTT) point of silicon is about 700-900 degrees Celsius. Silicon is ductile at temperatures greater than the DBTT point and brittle at temperatures below the DBTT point. The silicon crystals according to the present disclosure are formed with the specific concentration of boron at or near boron's solid-solubility limit at the DBTT point of silicon. If the boron concentration is more than boron's solid-solubility limit at the DBTT point of silicon, boron precipitates (SiBx, x>1) can be formed in silicon during cool-down. The silicon crystals according to the present disclosure have boron concentration between 0.05 wt % and 0.5 wt %, preferably between 0.1 wt % and 0.3 wt % (the notation wt % is explained below). The silicon crystals manufactured with the specific concentration of boron according to the present disclosure resist halogen plasma more than silicon crystals with lower boron concentration. In contrast, silicon with boron concentration of 8.5E18 atoms/cm3 (or 0.0065 wt %), which is currently used to manufacture components of processing chambers, etches up to ˜50% faster than the silicon crystals formed with the specific concentration of boron according to the present disclosure.

Before describing the methods used to manufacture the silicon crystals with the specific concentration of boron according to the present disclosure, a notation used throughout the present disclosure to describe purity of the materials used in the manufacture is briefly explained. Nines, denoted as nN, where n is a positive integer, is an informal, logarithmic notation used for denoting proportions of materials very near to one, or equivalently for denoting percentages of materials very near 100%. Nines are used in grading purity of materials. Nines are a number of consecutive nines in a percentage such as 99% (two nines) or in a decimal fraction such as 0.999 (three nines). The number of nines of a proportion X is expressed as: Nines=−log₁₀ (1−X). Thus, 99.99% is denoted as 4N; 99.9999% is denoted as 6N; and so on. Ideally, a totally pure material (X=1) will have infinite number of nines.

In addition, the notation wt % is used throughout the present disclosure. Generally, a mass fraction of a substance in a mixture is a ratio wᵢ of mass mᵢ of the substance to a total mass mₜₒₜ of the mixture. The mass fraction is expressed as: wᵢ=mᵢ/mₜₒₜ. Since individual masses of the ingredients of a mixture add to mₜₒₜ, a sum of the mass fractions of the ingredients of the mixture is unity, as shown in the following equation.

$${\sum }_{i = 1}^{n} {w}_{i} = 1$$

The mass fraction can also be expressed, with a denominator of 100, as a percentage by mass, which is also called percentage by weight and is abbreviated as wt %. Accordingly, in 100 grams of a mixture of substances P and Q, if the proportion of substance Q is x wt %, 100 grams of the mixture includes x grams of the substance Q. For example, in 100 grams of a mixture of substances P and Q, if the proportion of substance Q is 0.2 wt %, 100 grams of the mixture includes 0.2 grams of the substance Q. Stated generally, in G grams of a mixture of substances P and Q, if proportion of substance Q is x wt %, G grams of the mixture includes (x*G/100) grams of the substance Q.

Impurities can also be expressed as parts-per-million (ppm), which is a number of units of mass of a contaminant per million units of a total mass (therefore also called ppm-mass or ppmw). For example, an impurity of 1 ppmw of a contaminant in a substance means 1 Kg of the substance includes 1 mg of the contaminant. Thus, throughout the present disclosure, when a reference is made to a mixture having (or a component made from a mixture having) high purity silicon (>6N) and high purity dopant (>4N), what is meant is that the mixture or the component has impurities (other than the silicon or the dopant) of less than 10\hat{ }−6 g/g or less than 0.000001 g/g or less than 0.0001 wt % or less than 1 ppmw (ppm mass). Similarly, high purity dopant (>4N) means that the dopant has impurities of less than 10\hat{ }−4 g/g or less than 0.0001 g/g or less than 0.01 wt % or less than 100 ppmw (ppm mass).

Various methods can be used to grow silicon crystals with the desired boron concentration according to the present disclosure. For example, silicon crystals can be grown using DSS, where a mixture of high purity silicon (>6N) and high purity boron (>4N) with weight concentration between 0.05 wt % and 0.5 wt %, preferably between 0.1 wt % and 0.3 wt % is melted in a furnace, which is followed by solidification from the bottom of the molten silicon. Alternatively, single crystals of silicon can be grown using the CZ process, where a mixture of high purity silicon (>6N) and high purity boron (>4N) with weight concentration between 0.05 wt % and 0.5 wt %, preferably between 0.1 wt % and 0.3 wt % is melted in a furnace, which is followed by pulling the silicon ingot from the molten silicon. Silicon crystals can also be grown using the CCZ process, where high purity silicon (>6N) and high purity boron (>4N) are fed into molten silicon while the silicon ingot is being pulled so that boron concentration in the silicon crystal can be controlled precisely and a relatively long silicon ingot can be grown. Preferably, in the CCZ process, silicon and boron are fed into the molten silicon at a ratio to maintain a weight concentration of boron from top to bottom in the silicon ingot between 0.05 wt % and 0.5 wt %, preferably between 0.1 wt % and 0.3 wt % so that boron precipitates (SiBx, x>1) are not formed. Accordingly, the CCZ process can control boron concentration much more precisely than the CZ process.

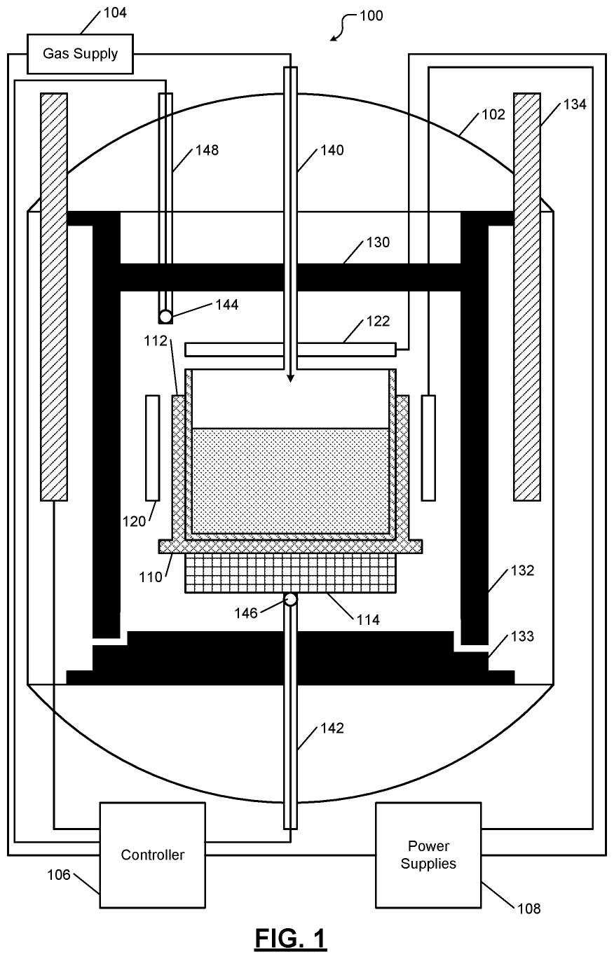

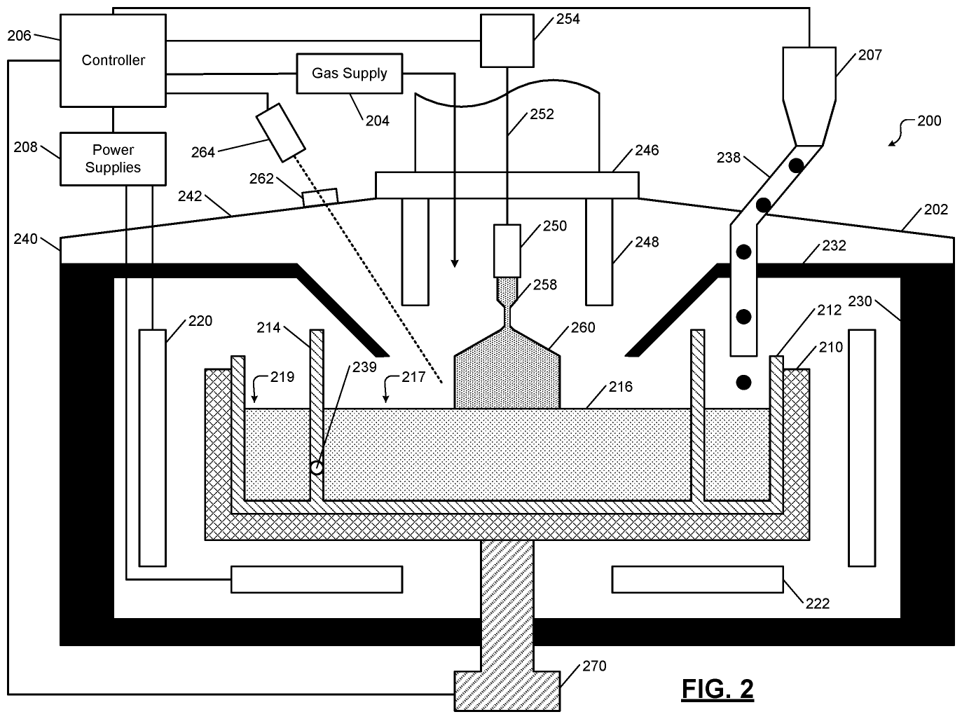

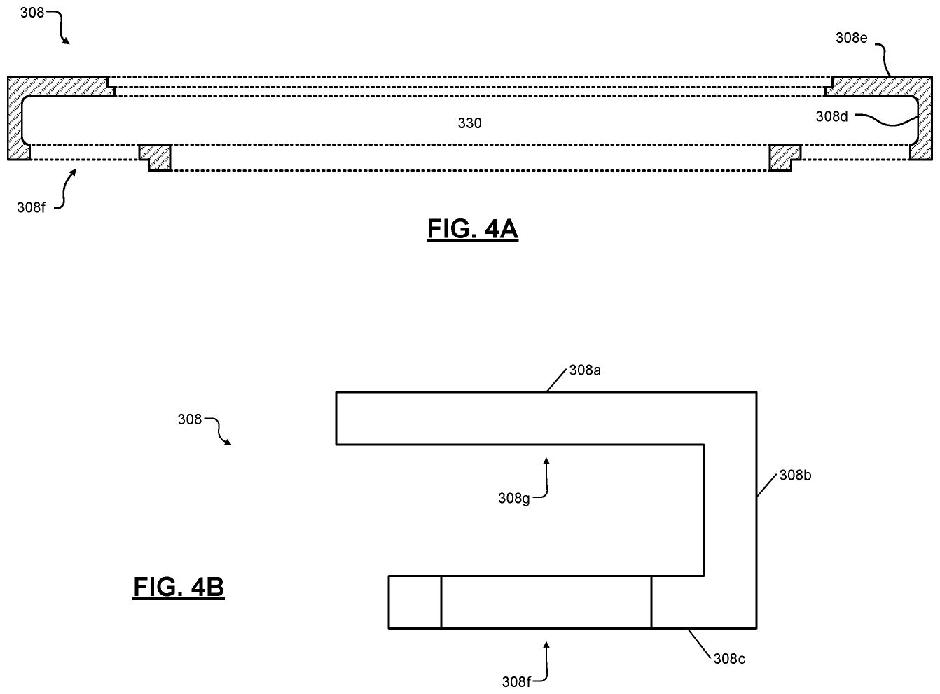

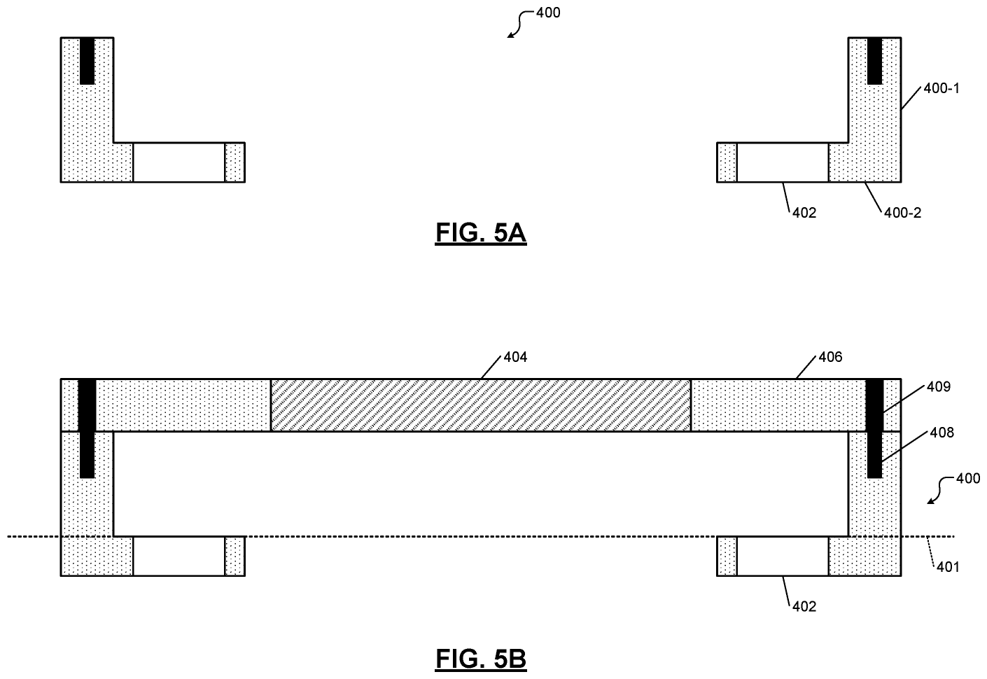

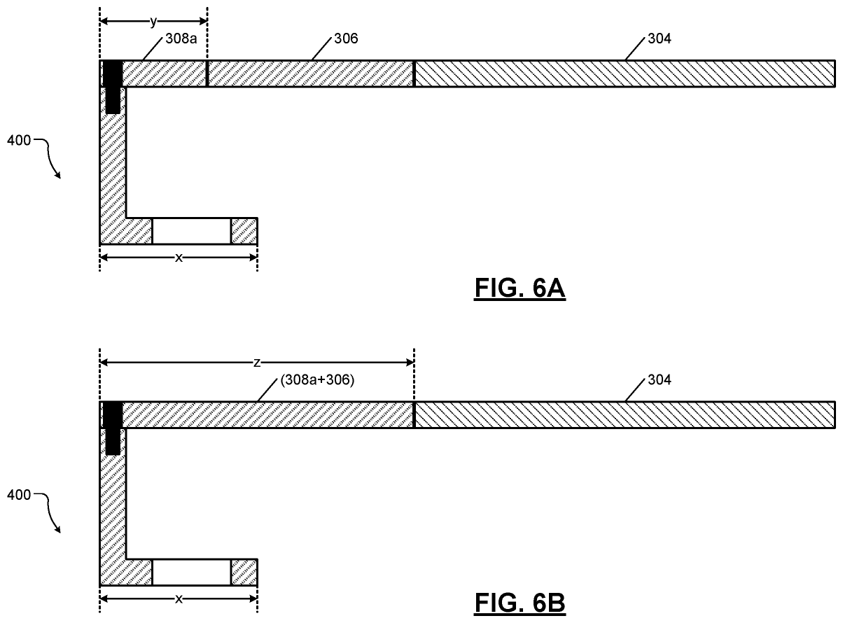

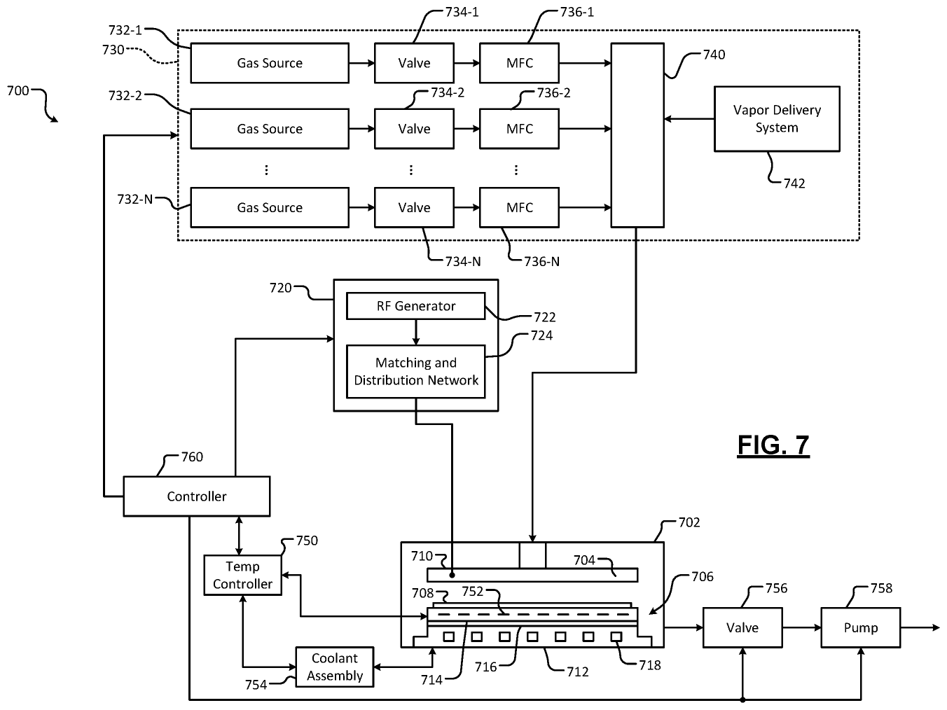

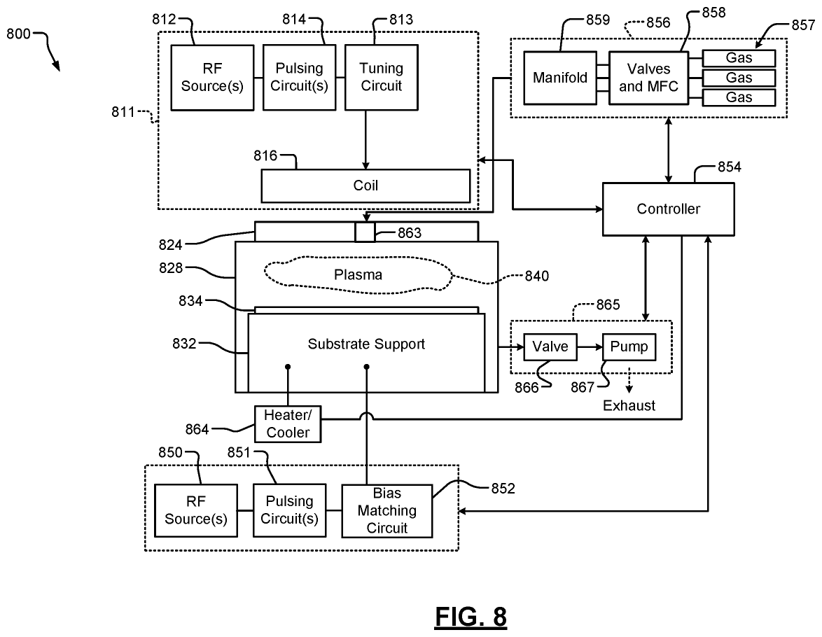

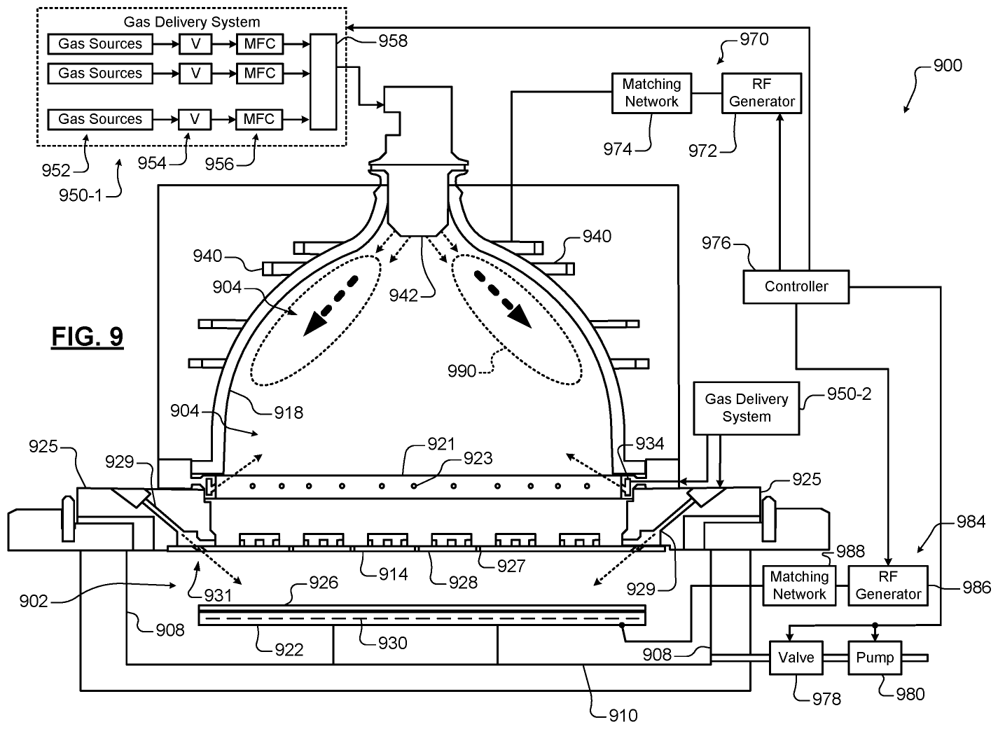

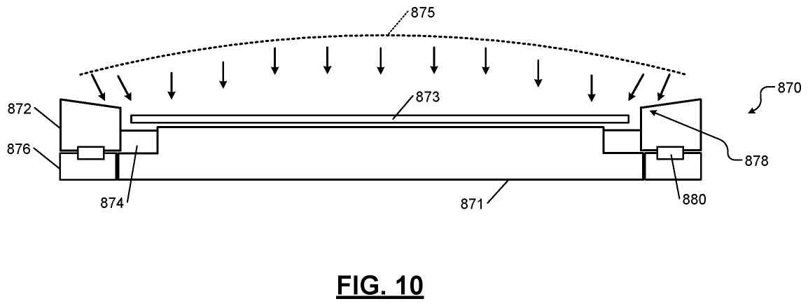

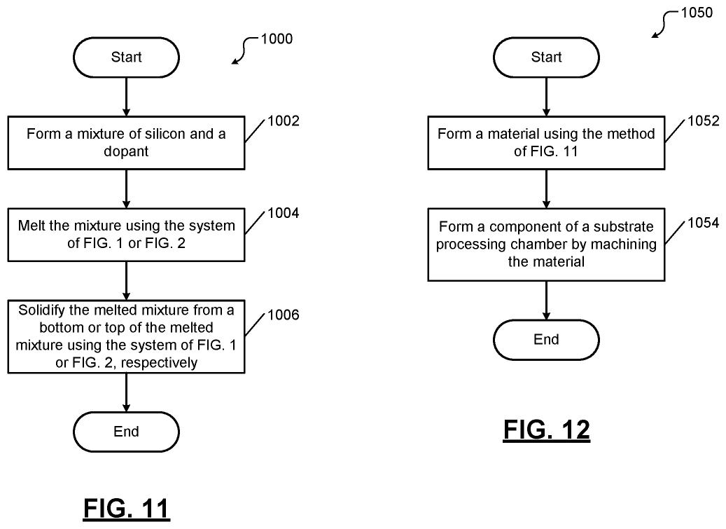

The present disclosure is organized as follows. Examples of DSS and CCZ systems for manufacturing silicon ingots with a specific boron concentration according to the present disclosure are shown and described with reference to FIGS. 1 and 2. An example of a plasma processing chamber is shown and described with reference to FIG. 3. The example shows a C-shaped plasma confinement ring or shroud, which is shown and described in further detail with reference to FIGS. 4A and 4B. An etch-resistant C-shaped plasma confinement ring can be manufactured from silicon ingots produced using the systems of FIGS. 1 and 2. An example of an L-shaped confinement ring for use in the plasma processing chamber of FIG. 3 is shown and described with reference to FIG. 5A. An etch-resistant L-shaped confinement ring can be manufactured from silicon ingots produced using the systems of FIGS. 1 and 2. An example of a C-shaped shroud formed using the L-shaped confinement ring for use in the plasma processing chamber of FIG. 3 is shown and described with reference to FIG. 5B. An etch-resistant C-shaped shroud formed using the L-shaped confinement ring can be manufactured from silicon ingots produced using the systems of FIGS. 1 and 2. Examples of embodiments utilizing the L-shaped confinement ring for use in the plasma processing chamber of FIG. 3 are shown and described with reference to FIGS. 6A and 6B. These embodiments utilizing the L-shaped confinement ring can be manufactured from silicon ingots produced using the systems of FIGS. 1 and 2. Additional examples of substrate processing systems comprising processing chambers are shown and described with reference to FIGS. 7-9. Various components of these processing chambers can be manufactured from silicon ingots produced using the systems of FIGS. 1 and 2. An example of an edge coupling ring for use in a processing chamber is shown and described with reference to FIG. 10. An etch-resistant edge coupling ring can be manufactured from silicon ingots produced using the systems of FIGS. 1 and 2. A method of forming a material comprising silicon and a dopant using the system of FIG. 1 or FIG. 2 is shown and described with reference to FIG. 11. A method of forming a component by machining the material formed using the method of FIG. 11 is shown in FIG. 12.

FIG. 1 shows a schematic of a directional solidification system (DSS) 100. The DSS system 100 comprises a double-walled and water-cooled stainless-steel chamber (hereinafter the furnace) 102, a gas supply 104, a controller 106, and power supplies 108. Additionally, the DSS system 100 also comprises a pump system and a water cooling system (both not shown). The furnace 102 comprises a susceptor 110 and a crucible 112 in which a silicon charge 116 is melted. A heat exchanger 114 is arranged at the bottom of the susceptor 110. A side heater 120 is arranged surrounding the sides of the susceptor 110. A top heater 122 is arranged above the susceptor 110. The susceptor 110, the crucible 112, the heat exchanger 114, and the heaters 120, 122 are enclosed in a thermal insulation cage 130 within the furnace 102. The thermal insulation cage 130 comprises an upper portion 132 and a lower portion 133. The upper portion 132 is connected to a lift assembly 134 that can lift the upper portion 132 during the solidification and cool down processes described below.

A first conduit 140 extends from a top center portion of the furnace 102 vertically downwards up to the top of the crucible 112. The gas supply 104 supplies an inert gas (e.g., argon) through the first conduit 140. A viewing port (not shown) is arranged on the furnace 102 near a top end of the first conduit 140. A second conduit 148 extends from a top side portion of the furnace 102 vertically downwards through and along an inner side of the upper portion 132 of the thermal insulation cage 130 up to a location proximate to the top heater 122 and the top of the crucible 112. A first temperature sensor (e.g., a thermocouple) 144 is disposed through the second conduit 148 and is arranged near a distal end of the second conduit 148.

A third conduit 142 extends from a bottom center portion of the furnace 102 vertically upwards up to a bottom of the heat exchanger 114. A second temperature sensor (e.g., a thermocouple) 146 is disposed through the third conduit 142 and is arranged near a distal end of the third conduit 142. The controller 106 controls the power supplies 108 that supply power to the heaters 120, 122 and controls the temperature of melted silicon in the crucible 112 based on temperatures sensed by the first and second temperature sensors 144, 146. The controller 106 also controls the gas supply 104 that supplies an inert gas (e.g., argon) through the first conduit 140 into the furnace 102. The controller 106 also controls the position of the upper portion 132 of the thermal insulation cage 130 by controlling the lift assembly 134

For example, multi-crystalline silicon ingots weighing about 1500 kg and having a shape of a pseudo square about 1.3m wide can be grown using the DSS system 100 as follows. A charge containing a mixture of 1500 kg of high purity (>6N) silicon chunks and/or granules and 3000 g of high purity (>4N) boron is depositing into the crucible 112. The crucible 112 is made of quartz coated with Si₃N₄. The crucible 112 is loaded into the furnace 102. The controller 106 supplies power to the heaters 120, 122. The heaters 120, 122 generate heat, which melts the charge as shown at 116.

The controller 106 controls the heaters 120, 122 such that the DSS system 100 grows a multi-crystalline silicon ingot at a rate between 0.2 cm/hr to 1 cm/hr. The grown silicon ingot is then annealed at ˜1200C for about 5-10 hours. The annealed silicon ingot is then allowed to slowly cool down to about 700C at a rate of <2C/min. The slow cool down is followed by a faster cool down of the annealed silicon ingot to about 400C. The faster cool down is achieved by shutting off the power supply to the heaters 120, 122 and by fully opening the thermal insulation cage 130. For example, the thermal insulation cage 130 is opened by lifting the upper portion 132 of the thermal insulation cage 130 above the heat exchanger 112 using the lift assembly 134. At 400C, the furnace 102 is backfilled with the inert gas (e.g., argon) supplied by the gas supply 104, and the furnace 102 is opened to let the silicon ingot cool down to room temperature. Thereafter, the silicon ingot can be sliced and machined to manufacture parts that can be used in the processing chambers.

Since the weight concentration of boron in the silicon charge is 0.1%˜0.3%, boron precipitates are not formed in the silicon ingot. Consequently, when parts made from the silicon ingot with weight concentration of boron between 0.1%˜0.3% are exposed to halogen plasma in substrate processing chambers, the parts exhibit significant resistance to etching by halogen plasma.

FIG. 2 shows a system 200 implementing the continuous Czochralski pulling method (CCZ) to grow silicon ingots according to the present disclosure. The system 200 comprises a double-walled and water-cooled stainless-steel chamber (hereinafter the furnace) 202, a gas supply 204, a controller 206, a charge hopper 207, and power supplies 208. Additionally, the system 200 also comprises a pump system and a water cooling system (both not shown). The furnace 202 comprises a susceptor 210 and a crucible 212 made of quartz. The crucible 212 includes an annular wall 214 that partitions the crucible 212 into a radially inner zone 217 and a radially outer zone 219. A side heater 220 is arranged surrounding the sides of the susceptor 210. A bottom heater 222 is arranged under the susceptor 210. The controller 206 controls the power supplies 208 that supply power to the heaters 220, 222. A silicon charge 216 is melted in the crucible 212 using the heaters 220, 222.

The susceptor 210, the crucible 212, and the heaters 220, 222 are surrounded on sides and at bottom with a thermal insulation cage 230 and are partially covered on top by a radiation shield 232. The thermal insulation cage 230 is formed along a cylindrical sidewall 240 of the furnace 202. The radiation shield 232 extends radially inwards from the top end of the thermal insulation cage 230 up to a first distance and then descends angularly towards the center of the crucible 212 up to a second distance. The angularly descending portion of the radiation shield 232 extends over the annular wall 214 of the crucible 212.

The furnace 202 further comprises a top dome 242 that ascends angularly and radially inwards from a top end of the cylindrical sidewall 240 up to a gate valve 246 located at a top center region of the furnace 202. A feeding tube 238 extends from the charge hopper 207 into the furnace 202 through the top dome 242. Small chips and/or granules of silicon and boron (also called the silicon/boron charge) are supplied by the charge hopper 207 through the feeding tube 238. A distal end of the feeding tube 238 is aligned with the radially outer zone 219 of the crucible 212. That is, the distal end of the feeding tube 238 is aligned between the sidewall of the crucible 212 and the annular wall 214 in the crucible 212. Accordingly, the small chips and/or granules of silicon and boron drop into the melted charge 216 in the radially outer zone 219 of the crucible 212 (i.e., between the sidewall of the crucible 212 and the annular wall 214 of the crucible 212). The controller 206 controls the charge hopper 207 to control a feed rate of the silicon/boron charge through the feeding tube 238 into the melted charge 216 in the radially outer zone 219 of the crucible 212.

A small transport hole 239 is located near the bottom of the annular wall 214 of the crucible 212. The temperature of the small chips and/or granules of silicon and boron falling into the melted charge 216 is significantly lower than the temperature of the melted charge 216. The temperature variation of the melted charge 216 in the radially outer zone 219 can be much larger than the temperature variation of the melted charge 216 in the radially inner zone 217. Due to the small transport hole 239, the melted charge 216 in the radially outer zone 219 slowly mixes with the melted charge 216 in the radially inner zone 217. Due to the slow mixing, the large temperature variation of the melted charge 216 in the radially outer zone 219 due to the feeding of the relatively cooler silicon/boron charge hardly affects the temperature stability of the melted charge 216 in the radially inner zone 217.

The furnace 202 further comprises a seed chuck 250 that is connected to a pulling cable 252. A distal end of the pulling cable 252 is connected to a seed lift and rotation assembly 254. A seed chuck 250 is connected to a seed crystal 258. The controller 206 controls the seed lift and rotation assembly 254. The seed lift and rotation assembly 254 pulls the pulling cable 252, which pulls a silicon ingot 260 (ingot formation is described below) while rotating the silicon ingot 260. The furnace 202 further comprises a cooling tube 248. A coolant such as water is circulated through the cooling tube 248 to cool the silicon ingot 260 while the silicon ingot 260 is pulled up from the melted charge 216. Additionally, the gas supply 204 supplies an inert gas (e.g., argon) into the furnace 202 for controlling SiO formed in the melted charge 216.

The furnace 202 further comprises a crucible rotation assembly 270 that rotates the crucible 212. The furnace 202 further comprises a view port 262. An optical device (e.g., a camera) 264 is arranged adjacent to the view port 262. The controller 206 can automatically control the diameter of the ingot 260 based on data received from the optical device 264. The controller 206 controls the heaters 220, 222 through the power supplies 208, the feed rate of the silicon/boron charge, the speed of the crucible rotation assembly 270, and the speed of the seed lift and rotation assembly 254 to control the formation of the silicon ingot 260.

In the Czochralski pulling method (CZ) method, single crystal silicon ingots weighing up to 400 kg and having a relatively large diameter (330 mm-460 mm) can be grown as follows. A charge containing a mixture of 400 kg of high purity (>6N) silicon and 1 kg of high purity (>4N) boron is deposited into a crucible. The crucible containing the charge is loaded into a furnace containing heaters that heat and melt the charge. A single crystalline silicon ingot is grown by dipping a seed into the melt followed by pulling a neck, crown, shoulder, body and tail of the seed. The thin neck is pulled relatively fast at a rate of about >3 mm/min. Subsequently, the pull rate is gradually reduced to about ˜0.5 mm/min to allow the body of the silicon ingot to grow straight at a diameter between 330 mm-460 mm. The silicon ingot is pulled out of the furnace by finally pulling a cone-shaped tail of the silicon ingot when the growth of the silicon ingot is completed. The grown single crystal silicon ingot is unloaded and allowed to cool in the air to room temperature.

In silicon ingots manufactured using the CZ method, the boron concentration in the silicon ingot may not be uniform throughout the silicon ingot due to boron segregating from silicon during ingot formation. For example, the boron concentration is slightly higher at the bottom of the silicon ingot and lower at the top of the silicon ingot. Accordingly, when parts made from the silicon ingot manufactured using the CZ method are used in substrate processing chambers and are exposed to halogen plasma, the etch resistance of the parts may slightly vary. Further, the etch resistance may vary more in parts made using the CZ method than in parts made using the DSS method since silicon ingots made using the CZ method are typically much longer than silicon ingots made using the DSS method. The longer length of silicon ingots made using the CZ method than silicon ingots made using the DSS method allows for more variation in boron concentration in the silicon ingots made using the CZ method than in the silicon ingots made using the DSS method.

The problem of varying boron concentration in relatively long silicon ingots made using the CZ method is solved by using the CCZ method instead as follows. In the CCZ method, a smaller melted charge 216 is used, and small chips or granules of silicon and boron are continuously depositing through the feeding tube 238 into the melted charge 216 while the silicon ingot is being pulled. Further, the crucible 212 is provided with the annular wall 214 and the transport hole 239. For example, single crystal silicon ingots weighing up to 400 kg and having a relatively large diameter (355 mm) can be grown using the CCZ method implemented by the system 200 as follows. The CCZ method is similar to the CZ method described above except for the following differences.

The melt size (i.e., the volume of the melted charge 216) is much smaller in CCZ, which allows improved temperature control of the radially inner zone 217 of the melted charge 216 in the CCZ method relative to the CZ method. For example, the melted charge 216 can contain about 100 kg of silicon and 280 g of boron. While the silicon ingot 260 is being pulled, the small chips or granules of silicon and boron are continuously fed through the feeding tube 238 into the radially outer zone 219 of the melted charge 216 to maintain the same melt level and the same boron concentration throughout the entire growth of the silicon ingot 260. Accordingly, in the silicon ingot 260 formed using the CCZ method, the boron concentration is uniform from top to bottom of the silicon ingot 260. Therefore, when parts made from the silicon ingot using the CCZ method are used in processing chambers and are exposed to halogen plasma, the etch resistance of the parts does not vary. In addition, using the CCZ method, the length of the silicon ingot 260 can be much longer than that using the CZ method. In the CCZ method, the length of the silicon ingot 260 is limited only by the ceiling height of the facility that houses the system 200, the mechanical strength of the thin neck of the silicon ingot 260, and the mechanical strength of the pulling cable 252.

Thus, the present disclosure provides a new composition of materials, specifically, a silicon crystal with boron concentration of 0.05 wt % and 0.5 wt %, preferably between 0.1 wt % and 0.3 wt %, in which boron precipitates (SiBx, x>1) are not formed at or near boron's solid solubility limit at temperatures of ductile-to-brittle transition point of silicon. In some examples, boron's solid solubility limit in silicon is found to be ˜0.2 wt %, which is ˜30 times larger than that in current commercially available low resistivity boron doped silicon (POR Si). The etch rate of the silicon crystal exposed to halogen plasma decreases as boron concentration increases to ˜0.2 wt %. Above this concentration, the etch rate increases due to strain induced in silicon by formation of boron precipitates (SiBx, x>1). Therefore, the silicon crystals manufactured according to the present disclosure have a narrow boron concentration range between 0.05 wt % and 0.5 wt %, preferably between 0.1 wt % and 0.3 wt %. The silicon crystals manufactured according to the present disclosure with the specific boron concentration resist etching due to halogen plasma up to ˜50% more than POR Si.

In addition to using the specific boron concentration, specific cooling sequence described above is used during the ingot formation to reduce formation of boron precipitates and ingot cracking. In the DSS system, rapid cooling of the silicon ingot when its temperature drops below the ductile-to-brittle transition point of silicon reduces both formation of boron precipitates and ingot cracking. As described above, the rapid cooling is also implemented in forming the ingots using the CZ and CCZ processes by using both radiation shields and water cooled tubes surrounding the ingot while the ingot is pulled. The ingots manufactured according to the present disclosure are relatively easier to grow and machine to form etch-resistant components than ingots formed using other materials. Therefore, the silicon crystals according to the present disclosure can be developed relatively faster and components machined therefrom can be deployed relatively faster than those made using other materials.

The present disclosure is not limited to doping silicon with boron, which is a Group IIIA element in the periodic table, and which is a p-type dopant. Alternatively, another p-type dopant or n-type dopant with purity greater than 4N can be mixed with silicon with purity greater than 6N using the systems and processes described above. For example, gallium, which is also a Group IIIA element in the periodic table, and which is also a p-type dopant can be mixed with silicon. Specifically, the silicon crystals manufactured according to the present disclosure can include silicon (>6N) mixed with gallium (>4N) with concentration between 0.05 wt % and 0.5 wt %, preferably between 0.1 wt % and 0.3 wt %.

Alternatively, phosphorous, arsenic, or antimony, which are Group VA elements in the periodic table, and which are n-type dopants can be mixed with silicon. Specifically, the silicon crystals manufactured according to the present disclosure can include silicon (>6N) mixed with phosphorous (>4N) with concentration between 0.5 wt % and 5.0 wt %, preferably between 1.0 wt % and 3.0 wt %. Alternatively, the silicon crystals manufactured according to the present disclosure can include silicon (>6N) mixed with arsenic (>4N) with concentration between 1.5 wt % and 15.0 wt %, preferably between 3.0 wt % and 10.0 wt %. In yet another alternative, the silicon crystals manufactured according to the present disclosure can include silicon (>6N) mixed with antimony (>4N) with concentration between 0.1 wt % and 1.0 wt %, preferably between 0.2 wt % and 0.7 wt %.

Notably, the segregation coefficient of gallium, phosphorous, arsenic, and antimony is much lower than that of boron in silicon crystal growth. A segregation coefficient is a ratio of concentration of an impurity in a liquid such as the melt to the concentration of the impurity in a solid. Due to the lower segregation coefficient of gallium, phosphorous, arsenic, and antimony, the CCZ process of manufacturing silicon crystals with gallium, phosphorous, arsenic, or antimony becomes an even more preferred method to grow these crystals with relatively low variation in the dopant concentration from top to bottom of the silicon ingots.

Note that the silicon crystals manufactured according to the present disclosure consist of only silicon and only one of the dopants as described above. The specific concentrations of the dopants described above provide unexpected results. Specifically, with the specific concentrations of the dopants, both absence of precipitates and low etch rates upon exposure to halogen plasma are observed in the silicon crystals. These unexpected results cannot be obtained when dopants with concentrations other than those described above are used.

Examples of components of processing chambers that can be manufactured from the silicon ingots produced according to the present disclosure are now described. An example of a plasma processing chamber utilizing a C-shaped confinement shroud, an upper electrode, and an edge ring is shown and described with reference FIG. 3. The C-shaped confinement shroud is shown and described with reference to FIGS. 4A and 4B. An L-shaped confinement ring and an upper electrode are shown and described with reference to FIGS. 5A and 5B. Examples of embodiments utilizing the L-shaped confinement ring in the plasma processing chamber of FIG. 3 are described with reference to FIGS. 6A and 6B.

A processing chamber of a substrate processing system may include a plasma confinement ring or shroud, an upper electrode, and an edge ring. Throughout the present disclosure, the terms shroud and confinement ring are used synonymously and interchangeably. The shroud may be arranged to confine plasma and other reactants within a desired region in the processing chamber. For example, the shroud may be positioned to surround a substrate support and an upper electrode to confine the plasma within a volume above a substrate and below the upper electrode. An etch-resistant shroud, an upper electrode, and an edge ring can be made from the silicon ingots produced according to the present disclosure.

Typically, the plasma confinement shrouds are C-shaped and are machined from a massive block of polycrystalline silicon. Slots or holes (hereinafter collectively called orifices) are fabricated in a lower portion of the C-shaped plasma confinement shrouds to vent gases out of a plasma confinement region within the C-shroud. In some examples, an L-shaped confinement ring or shroud can be used instead of the C-shaped plasma confinement shrouds. There is no upper portion in the L-shaped confinement ring. Consequently, orifices can be fabricated in a lower portion of the L-shaped confinement ring using any suitable method. The C- and L-shaped shrouds that are etch-resistant to halogen plasma can be manufactured from the silicon ingots produced according to the present disclosure.

FIG. 3 shows a partial cross-section of a plasma processing chamber (plasma chamber) 300. The plasma chamber 300 may be used for performing etching using RF plasma, deposition, and/or other suitable substrate processing. The plasma chamber 300 includes a substrate support assembly 302, an upper electrode including a center electrode plate (center electrode or inner electrode) 304 and an annular outer electrode (outer electrode) 306, and a confinement ring 308. The outer electrode 306 surrounds an outer edge of the inner electrode 304. For simplicity, throughout the present disclosure, the inner electrode and the outer electrode shown in FIGS. 3-6B are collectively called the upper electrode. For example, the upper electrode of the plasma chamber 300 includes the inner electrode 304 and the outer electrode 306 and is therefore collectively called the upper electrode 304, 306. A semiconductor substrate (not shown) is supported on the substrate support assembly 302 during processing.

The confinement ring 308 extends outwardly from the outer electrode 306. The confinement ring 308 includes a horizontal upper section (upper portion) 308a extending inwardly towards the outer electrode 306, a vertical section (side portion) 308b extending downwardly from an outer end of the upper portion 308a, and a horizontal lower section (lower portion) 308c extending inwardly from a lower end of the side portion 308b. The lower portion 308c includes a plurality of radially extending slots through which process gas and reaction byproducts are pumped out of the plasma chamber 300. The confinement ring 308 can include a slotted ring 310 below the lower portion 308c. The slotted ring 310 is rotatable and vertically movable relative to the lower portion 308c to adjust flow of process gas and reaction byproducts through the radially extending slots.

The substrate support assembly 302 comprises a movable ground ring 312, a lower electrode 314, an electrostatic chuck (ESC) 316 on which a semiconductor substrate is electrostatically clamped. The substrate support assembly 302 comprises an edge ring 318 having a plasma exposed surface surrounding the ESC 316. The substrate support assembly 302 comprises a dielectric ring 320 having a plasma exposed surface surrounding the edge ring 318. The substrate support assembly 302 comprises an insulator ring 322 beneath the edge ring 318. The substrate support assembly 302 comprises a fixed ground ring 324 of electrically conductive material beneath the dielectric ring 320. A portion 324a of the fixed ground ring 324 surrounds the insulator ring 322. The movable ground ring 312 is supported on depressible plungers 326 supported on a portion 324b of the fixed ground ring 324. The movable ground ring 312 is movable vertically relative to the fixed ground ring 324 so as to make electrical contact with the confinement ring 308. The substrate support assembly 302 is supported on an electrically grounded bias housing 328.

In the plasma chamber 300, the confinement ring 308 is C-shaped and is arranged in the form of a shroud around the upper electrode 304, 306 and the substrate support assembly 302 to confine plasma within a processing volume or a plasma region 330. Accordingly, the confinement ring 308 is also called a C-shaped confinement ring 308 or a C-shroud 308. In some examples, the confinement ring 308 comprises a semiconductor material, such as silicon (Si) or polysilicon (multi-crystalline silicon). The confinement ring 308 may include one or more orifices (e.g., radial slots) arranged to allow gases to flow out of the plasma region 330 to be vented from the plasma chamber 300. The confinement ring 308 can be made from the silicon ingots produced according to the present disclosure.

FIG. 4A shows a cross-section of the confinement ring 308. The confinement ring 308 includes inner, plasma-facing surfaces 308d and outer, non-plasma-facing surfaces 308e. The confinement ring 308 may include one or more orifices 308f (e.g., holes or radial slots) for allowing gases to be vented out from the plasma region 330 within the confinement ring 308.

FIG. 4B shows the confinement ring 308 in further detail. The confinement ring 308 is annular. The confinement ring 308 is C-shaped and includes the upper portion 308a, the side portion 308b, and the lower portion 308c. The lower portion 308c includes the orifices 308f. The upper portion 308a extends to the upper electrode 304, 306 shown in FIG. 3.

FIG. 5A shows an L-shaped confinement ring 400. The L-shaped confinement ring 400 can be made from the silicon ingots produced according to the present disclosure. The L-shaped confinement ring 400 comprises a side portion (or cylindrical wall) 400-1 and a lower (ring-shaped) portion 400-2. The L-shaped confinement ring 400 does not include an upper portion similar to the upper portion 308a of the C-shaped confinement ring 308. Therefore, the L-shaped confinement ring 400 requires less silicon than the C-shaped confinement ring 108. A plurality of orifices 402 in the lower (ring-shaped) portion 400-2 of the L-shaped confinement ring 400 can be made using virtually any process. The L-shaped confinement ring 400 is easier to replace than the C-shaped confinement ring 108. Thus, the L-shaped confinement ring 400 provides both flexibility in manufacturing and ease of serviceability as compared to the C-shaped confinement ring 108. These advantages yield significant savings in time, material, and cost involved in manufacturing and servicing.

FIG. 5B shows a C-shaped shroud formed using the L-shaped confinement ring 400 and an upper electrode with an extended outer portion. The C-shaped shroud formed using the L-shaped confinement ring 400 and the upper electrode can be made from the silicon ingots produced according to the present disclosure. The C-shroud comprises an upper portion (i.e., an enlarged upper electrode comprising an inner electrode 404 and an outer electrode 406) and an L-shaped lower portion (i.e., the L-shaped confinement ring 400). The combination of the inner electrode 404 and the outer electrode 406 may be generally called the upper electrode or the upper electrode having an outer portion.

The L-shaped confinement ring 400 includes a lower ring (i.e., the lower portion 400-2 with a plurality of orifices 402) and a cylindrical wall (i.e., the side portion 400-1). The lower ring 400-2 and the cylindrical wall 400-1 are made of one piece. That is, the L-shaped confinement ring 400 is monolithic. The cylindrical wall 400-1 extends vertically or perpendicularly upwards from an outer edge of the lower ring 400-2. In a plasma chamber (e.g., the plasma chamber 300), the lower ring 400-2 is arranged along a plane 401 in which a substrate is arranged on the substrate support assembly in the plasma chamber. At a distal (upper) end of the cylindrical wall 400-1, the L-shaped confinement ring 400 comprises holes 408 to connect to the outer electrode 406 that extends radially outwardly from the inner electrode 404. The holes 408 may comprise threads for receiving screws through holes 409 in the outer electrode 406 with which the outer electrode 406 is screwed to the L-shaped confinement ring 400.

Notably, the L-shaped confinement ring 400 does not include an upper portion that is analogous to the upper portion 308a of the C-shaped confinement ring 308, which extends to the upper electrode 304, 306 as shown in FIG. 3. Instead, as FIG. 5B shows, the outer electrode 406 (analogous to element 306 of FIG. 3) extends from the inner electrode 404 (analogous to element 304 of FIG. 3) to the upper end of the side portion (i.e., the cylindrical wall) 400-1 of the L-shaped confinement ring 400. Accordingly, the inner electrode 404, the outer electrode 406, and the L-shaped confinement ring 400 can be used in place of the upper electrode 304, 306 and the C-shaped confinement ring 308 in the plasma chamber 300 of FIG. 3.

FIGS. 6A and 6B show examples of embodiments utilizing the L-shaped confinement ring 400 that can be used in the plasma chamber 300 of FIG. 3. Note that these drawings are not formal mechanical drawings. Rather, these drawings are simplified partial schematics for illustrating the use of the L-shaped confinement ring 400 in the plasma chamber 300 of FIG. 3. To further simplify the illustrations, the partial schematics provide views for only the left side of the plasma chamber 300. Although not shown, it is understood that the structures are similar on the right side of plasma chamber 300. The embodiments utilizing the L-shaped confinement ring 400 can be made from the silicon ingots produced according to the present disclosure.

In a first embodiment shown in FIG. 6A, the horizontal upper portion 308a is separate (i.e., distinct) from the L-shaped confinement ring 400 and is attachable to the L-shaped confinement ring 400 as shown. Further, the horizontal upper portion 308a projects inwardly towards the outer electrode 306 not as far as the lower horizontal portion of the L-shaped confinement ring 400 (i.e., y<x), and contacts the outer edge of the outer electrode 306.

In a second embodiment shown in FIG. 6B, the horizontal upper portion (shown as element 308a+306) is a single element comprising both elements 308a and 306. That is, element 308a is an integral part of or is integrated with element 306. The element (308a+306) can be called an outer electrode portion of the upper electrode 304, 306. The element (i.e., outer electrode) 308a+306 is separate (i.e., distinct) from the L-shaped confinement ring 400 and is attachable to the L-shaped confinement ring 400 as shown. Further, the element 308a+306 projects inwardly towards the inner electrode 304 farther than the lower horizontal portion of the L-shaped confinement ring 400 (i.e., z>x), and contacts the outer edge of the inner electrode 304.

FIGS. 7-9 show examples of substrate processing systems comprising processing chambers that can use halogen plasma for processing substrates. Various components used in these processing chambers that are exposed to halogen plasma can be manufactured from the silicon ingots formed according to the present disclosure. These components manufactured from the silicon ingots formed according to the present disclosure are etch resistant to halogen plasma used in the processing chambers for processing substrates

FIG. 7 shows an example of a substrate processing system 700 comprising a processing chamber 702. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or also other processing including etching processes. The system 700 comprises the processing chamber 702 that encloses other components of the system 700 and contains an RF plasma (if used). The processing chamber 702 comprises an upper electrode 704 and an electrostatic chuck (ESC) 706 or other substrate support. During operation, a substrate 708 is arranged on the ESC 706.

For example, the upper electrode 704 may include a gas distribution device 710 such as a showerhead that introduces and distributes process gases. The gas distribution device 710 may include a stem portion including one end connected to a top surface of the processing chamber 702. A base portion of the showerhead is generally cylindrical and extends radially outwardly from an opposite end of the stem portion at a location that is spaced from the top surface of the processing chamber 702. A substrate-facing surface or faceplate of the base portion of the showerhead includes a plurality of holes through which vaporized precursor, process gas, or purge gas flows. Alternately, the upper electrode 704 may include a conducting plate, and the process gases may be introduced in another manner.

The ESC 706 comprises a baseplate 712 that acts as a lower electrode. The baseplate 712 supports a heating plate 714, which may correspond to a ceramic multi-zone heating plate. A thermal resistance layer 716 may be arranged between the heating plate 714 and the baseplate 712. The baseplate 712 may include one or more channels 718 for flowing coolant through the baseplate 712.

If plasma is used, an RF generating system 720 generates and outputs an RF voltage to one of the upper electrode 704 and the lower electrode (e.g., the baseplate 712 of the ESC 706). The other one of the upper electrode 704 and the baseplate 712 may be DC grounded, AC grounded, or floating. For example, the RF generating system 720 may include an RF generator 722 that generates RF power that is fed by a matching and distribution network 724 to the upper electrode 704 or the baseplate 712. In other examples, the plasma may be generated inductively or remotely.

A gas delivery system 730 includes one or more gas sources 732-1, 732-2, . . . , and 732-N (collectively gas sources 732), where N is an integer greater than zero. The gas sources 732 are connected by valves 734-1, 734-2, . . . , and 734-N (collectively valves 734) and mass flow controllers 736-1, 736-2, . . . , and 736-N (collectively mass flow controllers 736) to a manifold 740. A vapor delivery system 742 supplies vaporized precursor to the manifold 740 or another manifold (not shown) that is connected to the processing chamber 702. An output of the manifold 740 is fed to the processing chamber 702.

A temperature controller 750 may be connected to a plurality of thermal control elements (TCEs) 752 arranged in the heating plate 714. The temperature controller 750 may be used to control the plurality of TCEs 752 to control a temperature of the ESC 706 and the substrate 708. The temperature controller 750 may communicate with a coolant assembly 754 to control coolant flow through the channels 718. For example, the coolant assembly 754 may include a coolant pump, a reservoir, and one or more temperature sensors (not shown). The temperature controller 750 operates the coolant assembly 754 to selectively flow the coolant through the channels 718 to cool the ESC 706. A valve 756 and pump 758 may be used to evacuate reactants from the processing chamber 702. A system controller 760 controls the components of the system 700.

In some applications, the ESC 706 may include an edge ring (an example is shown in FIG. 10) arranged around an outer portion (e.g., outside of and/or adjacent to a perimeter) of the ESC 706. The edge ring may be provided to modify a plasma sheath above the substrate 708, optimize substrate edge processing performance, protect the ESC 706 from erosion caused by the plasma, etc. A plasma confinement shroud (examples are shown in FIGS. 3-6B) may be arranged around each of the ESC 706 and the showerhead 710 to confine the plasma within the volume above the substrate 708.

Various components of the processing chamber 702 are exposed to the plasma used in the processing chamber 702 during substrate processing and during cleaning the processing chamber 702. Non-limiting examples of the components include electrodes, C- and L-shaped plasma confinement rings, and edge rings (examples are shown in FIGS. 3-6B and 10). These components can be manufactured by machining the silicon ingots formed according to the present disclosure. The components made from the silicon ingots formed according to the present disclosure exhibit relatively high etch-resistance (i.e., relatively low etch rate) to halogen plasma used in the processing chamber 702 during substrate processing and during cleaning the processing chamber 702.

FIG. 8 shows another example of a substrate processing system 800. While the substrate processing system 700 uses capacitively coupled plasma (CCP), the substrate processing system 800 uses transformer coupled plasma (TCP). The substrate processing system 800 includes a coil driving circuit 811. In some examples, the coil driving circuit 811 includes an RF source 812, a pulsing circuit 814, and a tuning circuit (i.e., matching circuit) 813. The pulsing circuit 814 controls a transformer coupled plasma (TCP) envelope of an RF signal generated by the RF source 812 and varies a duty cycle of TCP envelope between 1% and 99% during operation. As can be appreciated, the pulsing circuit 814 and the RF source 812 can be combined or separate.

The tuning circuit 813 may be directly connected to an inductive coil 816. While the substrate processing system 800 uses a single coil, some substrate processing systems may use a plurality of coils (e.g., inner and outer coils). The tuning circuit 813 tunes an output of the RF source 812 to a desired frequency and/or a desired phase, and matches an impedance of the coil 816.

A dielectric window 824 is arranged along a top side of a processing chamber 828. The processing chamber 828 comprises a substrate support (or pedestal) 832 to support a substrate 834. The substrate support 832 may include an electrostatic chuck (ESC), or a mechanical chuck or other type of chuck. Process gas is supplied to the processing chamber 828 and plasma 840 is generated inside of the processing chamber 828. The plasma 840 etches an exposed surface of the substrate 834. An RF source 850, a pulsing circuit 851, and a bias matching circuit 852 may be used to bias the substrate support 832 during operation to control ion energy.

A gas delivery system 856 may be used to supply a process gas mixture to the processing chamber 828. The gas delivery system 856 may include process and inert gas sources 857, a gas metering system 858 such as valves and mass flow controllers, and a manifold 859. A gas injector 863 may be arranged at a center of the dielectric window 824 and is used to inject gas mixtures from the gas delivery system 856 into the processing chamber 828. Additionally or alternatively, the gas mixtures may be injected from the side of the processing chamber 828.

A heater/cooler 864 may be used to heat/cool the substrate support 832 to a predetermined temperature. An exhaust system 865 includes a valve 866 and pump 867 to control pressure in the processing chamber and/or to remove reactants from the processing chamber 828 by purging or evacuation.

A controller 854 may be used to control the etching process. The controller 854 monitors system parameters and controls delivery of the gas mixture; striking, maintaining, and extinguishing the plasma; removal of reactants; supply of cooling gas; and so on. Additionally, as described below, the controller 854 may control various aspects of the coil driving circuit 811, the RF source 850, and the bias matching circuit 852, and so on.

In some applications, the substrate support 832 may include an edge ring (an example is shown in FIG. 10) arranged around an outer portion (e.g., outside of and/or adjacent to a perimeter) of the substrate support 832. The edge ring may be provided to modify a plasma sheath above the substrate 834, optimize substrate edge processing performance, protect the substrate support 832 from erosion caused by the plasma, etc. A plasma confinement shroud (examples are shown in FIGS. 3-6B) may be arranged around the substrate support 832 to confine the plasma within the volume above the substrate 834.

Various components of the processing chamber 828 are exposed to the plasma used in the processing chamber 828 during substrate processing and during cleaning the processing chamber 828. Non-limiting examples of the components include electrodes, C- and L-shaped plasma confinement rings, and edge rings (examples are shown in FIGS. 3-6B and 10). These components can be manufactured by machining the silicon ingots formed according to the present disclosure. The components made from the silicon ingots formed according to the present disclosure exhibit relatively high etch-resistance (i.e., relatively low etch rate) to halogen plasma used in the processing chamber 828 during substrate processing and during cleaning the processing chamber 828.

FIG. 9 shows a processing chamber 900 for etching a layer of a substrate. While the substrate processing system 700 uses capacitively coupled plasma (CCP), the substrate processing system 900 uses inductively coupled plasma (ICP). The processing chamber 900 includes a lower chamber region 902 and an upper chamber region 904. The lower chamber region 902 is defined by chamber sidewall surfaces 908, a chamber bottom surface 910, and a lower surface of a gas distribution device 914.

The upper chamber region 904 is defined by an upper surface of the gas distribution device 914 and an inner surface of a dome 918. In some examples, the dome 918 rests on a first annular support 921. In some examples, the first annular support 921 includes one or more spaced holes 923 for delivering process gas to the upper chamber region 904. In some examples, the process gas is delivered by the one or more spaced holes 923 in an upward direction at an acute angle relative to a plane including the gas distribution device 914, although other angles/directions may be used. In some examples, a gas flow channel 934 in the first annular support 921 supplies gas to the one or more spaced holes 923.

The first annular support 921 may rest on a second annular support 925 that defines one or more spaced holes 927 for delivering process gas from a gas flow channel 929 to the lower chamber region 902. In some examples, holes 931 in the gas distribution device 914 align with the holes 927. In other examples, the gas distribution device 914 has a smaller diameter, and the holes 931 are not needed. In some examples, the process gas is delivered by the one or more spaced holes 927 in a downward direction towards a substrate 926 at an acute angle relative to the plane including the gas distribution device 914, although other angles/directions may be used. In other examples, the upper chamber region 904 is cylindrical with a flat top surface and one or more flat inductive coils may be used. In still other examples, a single chamber may be used with a spacer located between a showerhead and the substrate support.

A substrate support 922 is arranged in the lower chamber region 904. In some examples, the substrate support 922 includes an electrostatic chuck (ESC), although other types of substrate supports can be used. The substrate 926 is arranged on an upper surface of the substrate support 922 during etching. In some examples, a temperature of the substrate 926 may be controlled by a heater plate 930, an optional cooling plate with fluid channels, and one or more sensors (not shown), although any other suitable substrate support temperature control system may be used.

In some examples, the gas distribution device 914 includes a showerhead (for example, a plate 928 having a plurality of spaced holes 927). The plurality of spaced holes 927 extend from the upper surface of the plate 928 to the lower surface of the plate 928. In some examples, the spaced holes 927 have a diameter in a range from 0.4″ to 0.75″ and the showerhead is made of a conducting material such as aluminum or a non-conductive material such as ceramic with an embedded electrode made of a conducting material.

One or more inductive coils 940 are arranged around an outer portion of the dome 918. When energized, the one or more inductive coils 940 create an electromagnetic field inside of the dome 918. In some examples, an upper coil and a lower coil are used. A gas injector 942 injects one or more gas mixtures from a gas delivery system 950-1.

In some examples, the gas delivery system 950-1 includes one or more gas sources 952, one or more valves 954, one or more mass flow controllers (MFCs) 956, and a mixing manifold 158, although other types of gas delivery systems may be used. A gas splitter (not shown) may be used to vary flow rates of a gas mixture. Another gas delivery system 950-2 may be used to supply an etch gas or an etch gas mixture to the gas flow channels 929 and/or 934 (in addition to or instead of etch gas from the gas injector 942).

In some examples, the gas injector 942 includes a center injection location that directs gas in a downward direction and one or more side injection locations that inject gas at an angle with respect to the downward direction. In some examples, the gas delivery system 950-1 delivers a first portion of the gas mixture at a first flow rate to the center injection location and a second portion of the gas mixture at a second flow rate to the side injection location(s) of the gas injector 942. In other examples, different gas mixtures are delivered by the gas injector 942. In some examples, the gas delivery system 950-1 delivers tuning gas to the gas flow channels 929 and 934 and/or to other locations in the processing chamber as will be described below.

A plasma generator 970 may be used to generate RF power that is output to the one or more inductive coils 940. Plasma 990 is generated in the upper chamber region 904. In some examples, the plasma generator 970 includes an RF generator 972 and a matching network 974. The matching network 974 matches an impedance of the RF generator 972 to the impedance of the one or more inductive coils 940. In some examples, the gas distribution device 914 is connected to a reference potential such as ground. A valve 978 and a pump 980 may be used to control pressure inside of the lower and upper chamber regions 902, 904 and to evacuate reactants.

A controller 976 communicates with the gas delivery systems 950-1 and 950-2, the valve 978, the pump 980, and the plasma generator 970 to control flow of process gas, purge gas, RF plasma and chamber pressure. In some examples, plasma is sustained inside the dome 918 by the one or more inductive coils 940. One or more gas mixtures are introduced from a top portion of the chamber using the gas injector 942 (and/or holes 923), and plasma is confined within the dome 918 using the gas distribution device 914.

Confining the plasma in the dome 918 allows volume recombination of plasma species and effusing desired etchant species through the gas distribution device 914. In some examples, there is no RF bias applied to the substrate 926. As a result, there is no active sheath on the substrate 926 and ions are not hitting the substrate with any finite energy. Some amount of ions will diffuse out of the plasma region through the gas distribution device 914. However, the amount of plasma that diffuses is an order of magnitude lower than the plasma located inside the dome 918. Most ions in the plasma are lost by volume recombination at high pressures. Surface recombination loss at the upper surface of the gas distribution device 914 also lowers ion density below the gas distribution device 914.

In other examples, an RF bias generator 984 is provided and includes an RF generator 986 and a matching network 988. The RF bias can be used to create plasma between the gas distribution device 914 and the substrate support or to create a self-bias on the substrate 926 to attract ions. The controller 976 may be used to control the RF bias.

In some applications, the substrate support 922 may include an edge ring (an example is shown in FIG. 10) arranged around an outer portion (e.g., outside of and/or adjacent to a perimeter) of the substrate support 922. The edge ring may be provided to modify a plasma sheath above the substrate 926, optimize substrate edge processing performance, protect the substrate support 922 from erosion caused by the plasma, etc. A plasma confinement shroud (examples are shown in FIGS. 3-6B) may be arranged around each of the substrate support 922 and the showerhead 914 to confine the plasma within the volume above the substrate 926.

Various components of the processing chamber 900 are exposed to the plasma used in the processing chamber 900 during substrate processing and during cleaning the processing chamber 900. Non-limiting examples of the components include electrodes, C- and L-shaped plasma confinement rings, and edge rings (examples are shown in FIGS. 3-6B and 10). These components can be manufactured by machining the silicon ingots formed according to the present disclosure. The components made from the silicon ingots formed according to the present disclosure exhibit relatively high etch-resistance (i.e., relatively low etch rate) to halogen plasma used in the processing chamber 900 during substrate processing and during cleaning the processing chamber 900.

In some processes, an edge coupling ring can be used to adjust an etch rate and/or etch profile of the plasma near a radially outer edge of the substrate. The edge coupling ring is typically located on the pedestal around the radially outer edge of the substrate. Process conditions at the radially outer edge of the substrate can be modified by changing a position of the edge coupling ring, a shape or profile of an inner edge of the edge coupling ring, a height of the edge coupling ring relative to an upper surface of the substrate, a material of the edge coupling ring, etc.

FIG. 10 shows an example of an edge coupling ring 870 surrounding a pedestal 871. The edge coupling ring 870 can be made from silicon ingots manufactured according to the present disclosure. The edge coupling ring 870 may include a single portion or two or more portions. In the example shown, the edge coupling ring 870 includes a first annular portion 872 arranged radially outside of a substrate 873. A second annular portion 874 is located radially inwardly from the first annular portion 872 below the substrate 873. A third annular portion 876 is arranged below the first annular portion 872.

During use, plasma 875 is directed at the substrate 873 to etch the exposed portions of the substrate 873. The edge coupling ring 870 is arranged to help shape the plasma such that uniform etching of the substrate 873 occurs. After the edge coupling ring 870 has been used, an upper surface of a radially inner portion of the edge coupling ring 870 may exhibit erosion (e.g., at 878). As a result, plasma 875 may tend to etch a radially outer edge of the substrate 873 at a faster rate than etching of radially inner portions thereof, and non-uniform etching of the substrate 873 may occur near a radially outer edge of the substrate 873. In some implementations, the edge coupling ring is located on 3 or more lift pins that transport the ring up gradually as its top surface gets eroded, to maintain an optimal value for edge coupling ring height above the ESC during the ring's lifetime. All of these components can be made from silicon ingots manufactured according to the present disclosure to prevent erosion.

For completeness, use of the edge coupling ring 870 is now described. One or more portions of the edge coupling ring 870 may be moved vertically and/or horizontally relative to a substrate or pedestal 871. The movement changes an edge coupling effect of the plasma 875 relative to the substrate 873 during etching or other substrate treatment without requiring the processing chamber to be opened. An actuator 880 may be arranged in various locations to move one or more portions of the edge coupling ring 870 relative to the substrate 873. For example only, the actuator 880 can be arranged between the first annular portion 872 and the third annular portion 876 of the edge coupling ring 870. In some examples, the actuator 880 may include a piezoelectric actuator, a stepper motor, a pneumatic drive, or other suitable actuator. In some examples, one, two, three, or four or more actuators are used. In other examples, multiple actuators can be arranged uniformly around the edge coupling ring 870. The actuators may be arranged inside or outside of the processing chamber.

The actuator 880 is used to move one or more portions of the edge coupling ring 870 to alter the position of the one or more portions of the edge coupling ring 870. For example, the actuator 880 may be used to move the first annular portion 872 of the edge coupling ring 870. In this example, the actuator 880 moves the first annular portion 872 of the edge coupling ring 870 in an upward or vertical direction such that an edge of the first annular portion 872 of the edge coupling ring 870 is higher relative to the radially outer edge of the substrate 873. As a result, etch uniformity near the radially outer edge of the substrate 873 is improved.

The actuator 880 may move in other directions such as horizontal, diagonal, etc. Horizontal movement of the portion of the edge coupling ring 870 may be performed to center the edge coupling effect relative to the substrate 873. For example, the actuator 880 may be arranged radially outside of the edge coupling ring 870. In addition, the actuator 880 can move in a vertical (or an up/down) direction as well as in a horizontal (or side to side) direction. Horizontal repositioning may be used when etching of the substrates shows a horizontal offset of the edge coupling ring 870 relative to the substrates. The horizontal offset may be corrected without opening the processing chamber. Likewise, tilting of the edge coupling ring 870 may be performed by actuating some of the actuators differently than others of the actuators to correct or create side-to-side asymmetry.

FIG. 11 shows a method 1000 of forming a material comprising a mixture of silicon and a dopant using the system of FIG. 1 or FIG. 2. At 1002, the method 1000 comprises forming a mixture of silicon and a dopant. The silicon comprises one or more impurities other than the silicon and the dopant of less than 1 ppm-mass (i.e., 1 ppmw). The dopant comprises one or more impurities of less than 100 ppm-mass (i.e., 100 ppmw). The dopant is selected from a group consisting of boron or gallium at a concentration of 0.05 wt % to 0.5 wt %, phosphorous at a concentration of 0.5 wt % to 5.0 wt %, arsenic at a concentration of 1.5 wt % to 15.0 wt %, and antimony at a concentration of 0.1 wt % to 1.0 wt %. In some examples, the concentration of the dopant can be in the ranges of 0.1 wt % to 0.3 wt % if the dopant is boron or gallium, 1.0 wt % to 3.0 wt % if the dopant is phosphorous, 3 wt % to 10 wt % if the dopant is arsenic, and 0.2 wt % to 0.7 wt % if the dopant is antimony.

At 1004, the method 1000 comprises melting the mixture using the system shown and described with reference to FIG. 1 or FIG. 2. At 1006, the method 1000 comprises solidifying the melted mixture using the system shown and described with reference to FIG. 1 or FIG. 2. A material formed using the method 100 is resistant to etching by the halogen plasma. The material also does not include precipitates of the dopant.

FIG. 12 shows a method 1050 of forming a component by machining the material formed using the method of FIG. 11. At 1052, the method 1050 comprises forming a material (e.g., a silicon crystal) using the method 1000. At 1054, the method 1050 comprises forming a component of a substrate processing chamber (e.g., any of the processing chambers shown in FIGS. 3 and 7-9) by machining the material. For example, the component can include any component of the processing chambers shown in FIGS. 3-10. For example, the component may include but is not limited to a C-shaped plasma confinement shroud, an L-shaped plasma confinement ring, an edge ring, an electrode, a sidewall of the substrate processing chamber, a window in the substrate processing chamber, and a dome of the substrate processing chamber. The component is resistant to etching when exposed to halogen plasma in the substrate processing chamber. The component also does not include precipitates of the dopant.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A component of a substrate processing chamber, the component comprising:
silicon;
a dopant selected from a group consisting of:
boron or gallium at a concentration of 0.05 wt % to 0.5 wt %;
phosphorous at a concentration of 0.5 wt % to 5.0 wt %;
arsenic at a concentration of 1.5 wt % to 15.0 wt %; and
antimony at a concentration of 0.1 wt % to 1.0 wt %; and
one or more impurities other than the silicon and the dopant of less than 1 ppm-mass.

2. The component of claim 1 wherein the dopant is boron or gallium.

3. The component of claim 1 wherein the dopant is boron.

4. The component of claim 1 wherein the concentration of the dopant is in the ranges of:
0.1 wt % to 0.3 wt % if the dopant is boron or gallium;
1.0 wt % to 3.0 wt % if the dopant is phosphorous;
3 wt % to 10 wt % if the dopant is arsenic; and
0.2 wt % to 0.7 wt % if the dopant is antimony.

5. The component of claim 1 wherein the component does not include precipitates containing the dopant.

6. The component of claim 1 wherein the component is at least one of a C-shaped plasma confinement shroud, an L-shaped plasma confinement ring, an edge ring, an electrode, a sidewall of the substrate processing chamber, a window in the substrate processing chamber, and a dome of the substrate processing chamber.

7. A method of forming a material, the method comprising:
forming a mixture of silicon and a dopant,
wherein the silicon comprises one or more impurities other than the silicon and the dopant of less than 1 ppm-mass;
wherein the dopant comprises one or more impurities of less than 100 ppm-mass; and
wherein the dopant is selected from a group consisting of:
boron or gallium at a concentration of 0.05 wt % to 0.5 wt %;
phosphorous at a concentration of 0.5 wt % to 5.0 wt %;
arsenic at a concentration of 1.5 wt % to 15.0 wt %; and
antimony at a concentration of 0.1 wt % to 1.0 wt %;
melting the mixture; and
solidifying the melted mixture to form the material.

8. The method of claim 7 wherein the dopant is boron, or gallium.

9. The method of claim 7 wherein the dopant is boron

10. The method of claim 7 wherein the concentration of the dopant is in the ranges of:
0.1 wt % to 0.3 wt % if the dopant is boron or gallium;
1.0 wt % to 3.0 wt % if the dopant is phosphorous;
3 wt % to 10 wt % if the dopant is arsenic; and
0.2 wt % to 0.7 wt % if the dopant is antimony.

11. The method of claim 7 wherein the material is resistant to etching by halogen plasma.

12. The method of claim 7 wherein the material does not include precipitates containing the dopant.

13. The method of claim 7 further comprising machining the material to form a component of a substrate processing chamber wherein the component is at least one of a C-shaped plasma confinement shroud, an L-shaped plasma confinement ring, an edge ring, an electrode, a sidewall of the substrate processing chamber, a window in the substrate processing chamber, and a dome of the substrate processing chamber.

14. The method claim 13 wherein the component is resistant to etching by halogen plasma when exposed to the halogen plasma in the substrate processing chamber.

15. The method claim 13 wherein the component does not include precipitates containing the dopant.
